(19) United States
(12) Patent Application Publication
(10) Pub. No.: US 2023/0317554 A1
(43) Pub. Date: Oct. 5, 2023

(54) EMBEDDED HEAT SLUG IN A SUBSTRATE

(71) Applicant: Qorvo US, Inc., Greensboro, NC (US)

(72) Inventors: Christine Blair, Lewisville, TX (US); MD Hasnine, Richardson, TX (US); Neftali Salazar, Oak Ridge, NC (US); George Kent, Richardson, TX (US)

(21) Appl. No.: 18/126,526

(22) Filed: Mar. 27, 2023

Related U.S. Application Data
(60) Provisional application No. 63/326,395, filed on Apr. 1, 2022.

(51) Int. Cl. H01L 23/42; H01L 23/31; H01L 23/498; H01L 21/54; H01L 21/48; H01L 23/00

(52) U.S. Cl. CPC H01L 23/42; H01L 21/486; H01L 21/4871; H01L 21/54; H01L 23/3107; H01L 23/49827; H01L 24/29; H01L 24/32; H01L 24/48; H01L 24/91; H01L 2224/29147; H01L 2224/32245; H01L 2224/48235; H01L 2224/9221; H01L 2924/1616

(57) ABSTRACT

A substrate includes a heat slug that is disposed in a cavity in the substrate. An engineered filler material is disposed in the cavity over, under, and/or around the heat slug. The engineered filler material is a thermally conductive particle material having a composition that can be adjusted based on a desired coefficient of thermal expansion. An electronic device can be attached to the substrate over the heat slug and the engineered filler material. The heat slug and the engineered filler material provide, or are part of, a heat transfer dissipation path for the electronic device.

### CROSS-REFERENCE TO RELATED APPLICATION(S)

This application claims the benefit of U.S. provisional Pat. application No. 63/326,395, filed on Apr. 1, 2022, and titled “EMBEDDED HEAT SLUG IN A SUBSTRATE”, the disclosure of which is expressly incorporated herein by reference in its entirety.

### FIELD OF THE DISCLOSURE

The disclosure relates generally to the packaging of integrated circuits, and more particularly to embedded heat slugs in substrates.

### BACKGROUND

The demand for smaller and more complex packages for electronic devices, such as integrated circuits, continues to increase. However, the generation of heat within a package can be an issue. Electronic devices, particularly high-powered electronic devices, generate heat during operation. In some instances, heat accumulation is aggravated by the higher packing density and smaller profile sizes.

A heat slug is typically embedded in a substrate of a package to dissipate heat generated by the electronic device. The heat slug is positioned in a cavity in the substrate and a non-conductive filler material is disposed in the cavity to fill the cavity area not consumed by the heat slug. The coefficients of thermal expansion (CTE) of the heat slug, the substrate, and the non-conductive filler material usually differ from one another, which means the heat slug, the substrate, and the non-conductive filler material expand and contract at different rates. The different expansion and contraction rates produce stress at the junctions between the heat slug, the non-conductive filler material, and the electronic device. Over time, the stress can cause cracks in the substrate or the electronic device, warpage of the substrate or the electronic device, and delamination of the electronic device from the substrate.

Additionally, it is common for heat slugs to be custom-sized due to the different sizes of electronic devices. A custom-sized heat slug enables the use of a wire bond that has as short a length as possible to connect the electronic device to another electronic component on the substrate. However, custom-sized heat slugs can increase both the cost to manufacture the heat slugs and the amount of time needed to manufacture the heat slugs.

### SUMMARY

The present disclosure relates to embedded heat slugs in substrates. A substrate includes a heat slug or a heat slug array that is disposed in a cavity in the substrate. An engineered filler material is disposed in the cavity over, under, and/or around the heat slug. The engineered filler material is a thermally conductive particle material having a composition that can be adjusted based on a desired coefficient of thermal expansion. An electronic device can be attached to the substrate over the heat slug and the engineered filler material. The heat slug and the engineered filler material provide, or are part of, a heat transfer dissipation path for the electronic device.

In one aspect, a substrate includes a heat slug disposed in a cavity in the substrate, and an engineered filler material disposed in the cavity over the heat slug. The heat slug is formed of a conductive material. The engineered filler material includes a conductive particle material.

In another aspect, an integrated circuit package includes a cavity formed in a substrate, a heat slug disposed in the cavity, and an engineered filler material disposed in the cavity over the heat slug. An electronic device is attached, via a die attach material, to the substrate over the heat slug. The heat slug is formed of a conductive material, and the engineered filler material includes a conductive particle material. The heat slug and the engineered filler material provide a heat transfer dissipation path for the electronic device.

In yet another aspect, a method includes disposing a heat slug in a cavity of a substrate and forming an engineered filler material in the cavity over the heat slug. The engineered filler material includes a conductive particle material. An electronic device is attached over the substrate. The heat slug and the engineered filler material provide a heat transfer dissipation path for the electronic device.

Those skilled in the art will appreciate the scope of the present disclosure and realize additional aspects thereof after reading the following detailed description in association with the accompanying drawings.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a first cross-sectional side view of an example integrated circuit package showing a substrate with a heat slug embedded therein in accordance with embodiments of the disclosure;

FIG. 2 illustrates a second cross-sectional side view of an example integrated circuit package showing a substrate with an embedded heat slug in accordance with embodiments of the disclosure;

FIG. 3 illustrates a third cross-sectional side view of an example integrated circuit package showing a substrate with an embedded heat slug in accordance with embodiments of the disclosure;

FIG. 4 illustrates an example flowchart of providing an integrated circuit package in accordance with embodiments of the disclosure;

FIG. 5 illustrates an example substrate with a cavity formed therein in accordance with embodiments of the disclosure;

FIG. 6 illustrates the substrate shown in FIG. 5 with a heat slug positioned in the cavity in accordance with embodiments of the disclosure;

FIG. 7 illustrates the substrate shown in FIG. 6 with a conductive particle material disposed in the cavity and around the heat slug in accordance with embodiments of the disclosure;

FIG. 8 illustrates the substrate shown in FIG. 7 with patterned conductive layers disposed over surfaces of the substrate in accordance with embodiments of the disclosure;

FIG. 9 illustrates the substrate shown in FIG. 8 with patterned mask layers disposed over surfaces of the substrate in accordance with embodiments of the disclosure;

FIG. 10 illustrates the substrate shown in FIG. 9 with an electronic device disposed over the heat slug and a wire bond attached between the electronic device and a conductive layer in accordance with embodiments of the disclosure; and

FIG. 11 illustrates an electronic device attached to the substrate shown in FIG. 10 in accordance with embodiments of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof. Additionally, the terms “attach,” “attached,” “on”, and “over” do not preclude the presence or addition of one or more other intervening features, elements, layers, and/or components.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The disclosure relates generally to providing heat transfer dissipation paths for an electronic device that is attached to a substrate. The substrate can be any suitable type of substrate. In one embodiment, the substrate is a laminate substrate. A heat slug is disposed in a cavity in the substrate. The heat slug is formed of a thermally conductive material. In one embodiment, the heat slug is formed of a thermally and electrically conductive material. In non-limiting nonexclusive examples, the heat slug includes at least one of: copper (Cu); molybdenum-copper (MoCu); copper-molybdenum-copper (known as “CMC”); copper-molybdenum/copper-copper (known as “CPC”); copper-molybdenum-copper-molybdenum-copper (known as “SCMC”); or aluminum nitride (AIN).

An engineered filler material is disposed in the cavity over, under, and/or around the heat slug. In a non-limiting embodiment, the engineered filler material is a thermally and electrically conductive particle material, such as a nano-copper (E-Cu) particle material. The engineered filler material has a coefficient of thermal expansion (CTE) that matches or substantially matches the CTE of the heat slug and/or the CTE of the substrate. Alternatively, the CTE of the engineered filler material bridges the CTEs of the heat slug and the substrate in that the CTE of the engineered filler material is between the CTEs of the heat slug and the substrate. Thus, the CTE of the engineered conductive material makes the difference between the CTE of the heat slug and the CTE of the substrate smaller or less significant.

The largest category of engineered filter materials (e.g., die attach, thermal via, or heat spreader materials) is made up of non-conductive epoxy resins that contain conductive particles such as copper (Cu) or silver (Ag). Copper and silver both possess good thermal and electrical conductivity. Engineered Copper Material (E-Cu) is a type of bulk copper material that has high surface activity and 99.9% purity. This E-Cu material is created through the reduction of simple copper salts in the presence of surfactants, resulting in particles ranging in size from five (5) to one hundred and fifty (150) nanometers. The surfactant composition is distinct, providing oxidation protection in ambient conditions but easily breaking down at elevated temperatures to allow the particles to fuse together, thereby transforming the material into bulk copper. The resulting copper exhibits a thermal conductivity of up to three hundred and thirty (330) W/mK and an electrical conductivity that is approximately thirty-five to seventy percent (35-70%) of that of bulk copper.

An electronic device can be attached to the substrate over the heat slug. The heat slug and the engineered filler material provide, or are part of, one or more heat dissipation paths for the electronic device. Additionally, in some embodiments, the heat slug and the engineered filler material electrically connect the electronic device to an electronic component or electronic device that is in or on the substrate, or that is separate from the substrate.

The engineered filler material increases the amount of surface that can be used to attach the electronic device to the substrate. In some instances, a design rule requires the electronic device to be placed within the full area of the heat slug when the electronic device is attached to the substrate to protect the electronic device from the issues created by the CTE mismatch. The engineered filler material increases the size of the area that the electronic device can be positioned within, which means the size of the electronic device may be larger.

Additionally or alternatively, the engineered filler material enables the distance between the electronic device and a wire bond finger to be reduced. The reduced distance means shorter wire bonds can be used. The engineered filler material can increase the thermal conductivity of the heat slug and may also be able to withstand higher temperatures over the lifetime of the electronic device compared to non-conductive filler materials.

In some embodiments, the engineered filler material reduces or eliminates the need to produce custom-sized heat slugs. The shape, composition, and/or size of heat slugs can be standardized. A number of heat slugs having various standard sizes, shapes, and compositions can be mass produced and/or made available on demand (or with less lead times). The amount of the engineered filler material that is used to fill a cavity can increase or decrease based on the standard shape and size of the heat slug. Thus, the engineered filler material enables the use of standard heat slugs.

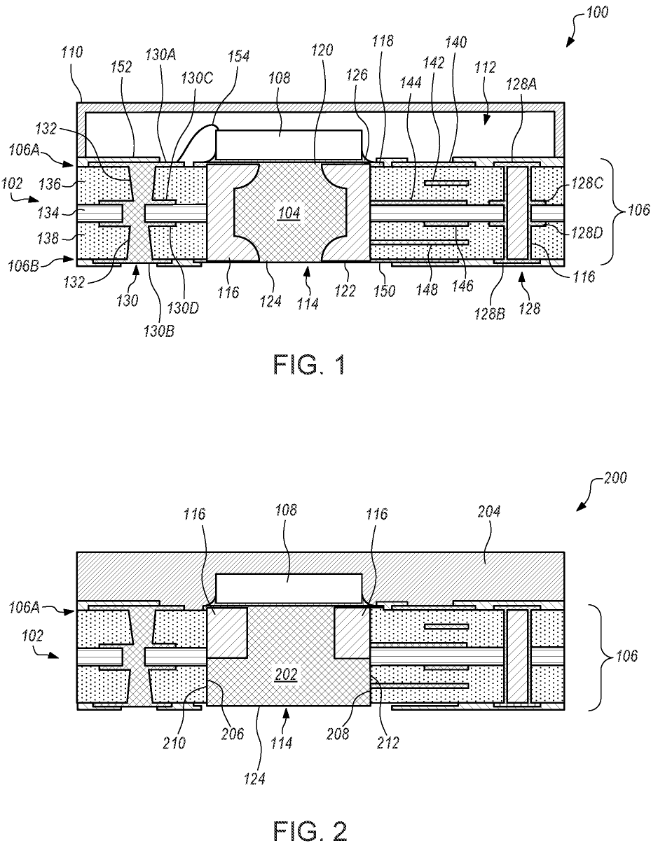

FIG. 1 illustrates a first cross-sectional side view of an example integrated circuit package 100 showing a substrate 102 with a heat slug 104 embedded therein in accordance with embodiments of the disclosure. The substrate 102 includes a substrate body 106 having a top surface 106A and a bottom surface 106B opposite the top surface 106A. An electronic device 108 is mounted over the substrate 102 and a lid 110 is mounted to the substrate 102 over the electronic device 108. The substrate 102 and the lid 110 define an air space 112 therebetween, with the electronic device 108 positioned within the air space 112.

In the illustrated embodiment, the substrate body 106 further includes a cavity 114 extending through the substrate body 106 from the top surface 106A to the bottom surface 106B. The heat slug 104 is disposed within the cavity 114. In one embodiment, the heat slug 104 is formed with a thermally conductive and electrically conductive material. The type of material to be included in the heat slug 104 can be based on factors such as the size of the heat slug 104, the thermal properties of the material, the rigidity of the material, and the type of electronic device 108. The size and shape of the heat slug 104 may be based on factors such as the aspect ratio of the electronic device, the size of the electronic device, and the cost of the material to be used in the heat slug 104. In non-limiting nonexclusive examples, the heat slug 104 includes at least one of Cu, MoCu, CMC, CPC, SCMC, or AIN. In other embodiments, the cavity 114 is disposed within the substrate body 106 but does not extend through the substrate body 106, and the heat slug 104 is positioned in the cavity.

The electronic device 108 contains components that generate heat during operation. Heat can cause thermal stress on the substrate 102 and/or the electronic device 108. The generated heat increases the temperature of the electronic device 108, which may impair the functional stability and service life of the electronic device 108. For example, the electronic device 108 can experience delamination, warpage, and/or cracking. The heat slug 104 is a thermal conducting element that provides, and is part of, one or more heat transfer dissipation paths for the heat generated by the electronic device 108.

The area above, below, and/or surrounding the heat slug 104 within the cavity 114 is filled with an engineered filler material 116. A desired CTE for the engineered filler material 116 can be used to determine the composition of the engineered filler material 116. In this manner, the engineered filler material 116 is tunable, in that the composition of the engineered filler material 116 can be adjusted to obtain (or substantially obtain) a particular CTE. The composition of the engineered filler material 116 can be adjusted based on the CTE of the substrate 102 and/or the CTE of the heat slug 104. In an example embodiment, the engineered filler material 116 is a nano-copper (E-Cu) particle material.

As described earlier, the engineered filler material 116 is a thermal conducting material that can be designed to match or substantially match the CTE of the substrate body 106 (e.g., the core layer 134 and the upper and lower dielectric layers 136, 138). In other embodiments, the engineered filler material 116 has a CTE that bridges the CTE of the heat slug 104 and the CTE of the substrate body 106 in that the CTE of the engineered filler material 116 is between the CTE of the substrate body 106 and the CTE of the heat slug 104. The CTE of the engineered filler material 116 balances and/or improves thermal conductivity to dissipate heat while minimizing or reducing the expansion of the heat slug 104 and/or the substrate 102. The engineered filler material 116 can reduce the thermal stresses experienced by the electronic device 108, thereby reducing or avoiding the adverse effects caused by the generated heat (e.g., warpage, cracking, delamination).

A top heat plate 118 is disposed over the top surface 106A of the substrate body 106 and contacts a top surface 120 of the heat slug 104. A bottom heat plate 122 is positioned over the bottom surface 106B of the substrate body 106 and contacts a bottom surface 124 of the heat slug 104. The electronic device 108 is attached to the top heat plate 118 with a die attach material 126. Any suitable die attach material can be used. In some embodiments, the engineered filler material 116 is used as the die attach material 126. Additionally, depending on the shape, size, and/or positioning of the heat slug 104, the top heat plate 118 can be omitted and the electronic device 108 attached directly to the top surface 120 of the heat slug 104.

The example substrate body 106 further includes a via structure 128 extending through the substrate body 106 from the top surface 106A to the bottom surface 106B. The via structure 128 may include a top via pad 128A that resides over the top surface 106A of the substrate body 106 and a bottom via pad 128B that resides over the bottom surface 106B of the substrate body 106. Some embodiments also include one or more inner via lines integrated in the substrate body 106, such as upper inner via line 128C and lower inner via line 128D. The top via pad 138A, the bottom via pad 138B, the upper inner via line 128C, and the lower inner via line 128D are formed of one or more conductive materials. One non-limiting example of a conductive material is copper. In one embodiment, the via structure 128 is formed as a via hole and the inner walls of the via hole are plated with a conductive material (e.g., copper). The via hole is then filled with the engineered filler material 116 that is designed to match or substantially match the CTE of the of the conductive material and/or the substrate body 106 (e.g., the core layer 134 and the upper and lower dielectric layers 136, 138). In other embodiments, the via hole of the via structure 128 may be filled with a conductive material or with a non-conductive material (e.g., an epoxy resin).

The example substrate body 106 also includes another via structure 130 extending through the substrate body 106 from the top surface 106A to the bottom surface 106B. The via structure 130 may include a top via pad 130A that resides over the top surface 106A of the substrate body 106 and a bottom via pad 130B that resides over the bottom surface 106B of the substrate body 106. Some embodiments also include one or more inner via lines integrated in the substrate body 106, such as upper inner via line 130C and lower inner via line 130D. The via structure 130 includes a number of via connections 132 coupling the top via pad 130A, the inner via lines 130C, 130D, and the bottom via pad 130B. In some applications, the via structure 130 may not include the inner via lines 130C, 130D, such that the via connections 132 directly connect the top via pad 130A and the bottom via pad 130B. The top via pad 130A, the bottom via pad 130B, and the inner via lines 130C, 130D are formed of a conductive material or materials. The via connections 132 may be formed as via holes, within which one or more electrically conductive materials are filled or plated. The via connections 132 may also be realized by plating the inner walls of the via holes with a conductive material, then filling the via holes with non-conductive materials such as epoxy resin. Although FIG. 1 depicts two via structures 128, 130, the substrate body 106 may include zero (no via structures) or one or more via structures 128, 130.

The example substrate body 106 further includes the core layer 134, the upper dielectric layer 136, and the lower dielectric layer 138. In FIG. 1, the core layer 134 is positioned between the upper and the lower dielectric layers 136, 138, although other embodiments are not limited to this configuration. In certain embodiments, the core layer 134 is a laminate layer, such as a glass-reinforced epoxy laminate material (e.g., FR-4 composite material).

The substrate body 106 further includes routing lines 140, 142, 144, 146, 148, 150. In the illustrated embodiment, the routing line 140 is disposed over the top surface 106A of the substrate body 106. The routing line 142 is positioned between the core layer 134 and the top surface 106A. The routing lines 144, 146 are disposed between the core layer 134 and the dielectric layers 136, 138. The routing line 148 is positioned between the core layer 134 and the bottom surface 106B. The routing line 150 is disposed over the bottom surface 106B of the substrate body 106. In other embodiments, the substrate body 106 may include any number of core layers 134, dielectric layers 136, 138, and routing lines 140, 142, 144, 146, 148, 150 arranged in any suitable assembly.

When the engineered filler material 116 is both thermally and electrically conductive, and the die attach material 126 is electrically conductive, one or more routing lines may be electrically connected to the electronic device 108 through the die attach material 126, the heat slug 104, and the engineered filler material 116. For example, the example routing lines 144, 148 are electrically connected to the engineered filler material 116, which means the electronic device is electrically connected to the through the engineered filler material 116 and the heat slug 104. Additionally, an electrical component (not shown) can be electrically connected to the bottom heat plate 122, which in turn electrically connects the electronic component to the electronic device 108 through the die attach material 126, the heat slug 104, and the engineered filler material 116.

The example substrate 102 further includes mask layers 152 to cover at least portions of the top and bottom via pads 128A, 128B, 130A, 130B and the routing lines 140, 150. The mask layers are used to control the exposure of the top and bottom via pads 128A, 128B, 130A, 130B and the routing lines 140, 150. One or more wire bonds electrically connect the electronic device 108 to at least one of the top via pads 128A, 130A or the routing line140. In the illustrated embodiment, the wire bond 154 electrically connects the electronic device 108 to the top via pad 130A.

Additionally, in some embodiments, the heat slug 104 is operable to propagate a signal (e.g., a radio frequency signal). In other embodiments, the heat slug 104 is electrically grounded. For example, the bottom heat plate 122 can be a ground plane. Since the heat slug 104 is electrically connected to the bottom heat plate 122, the heat slug is electrically grounded.

FIG. 2 illustrates a second cross-sectional side view of an example integrated circuit package 200 showing a substrate 102 with a heat slug 202 embedded therein in accordance with embodiments of the disclosure. The integrated circuit package 200 is similar to the integrated circuit package shown in FIG. 1 except for the shape of the heat slug 202 and the overmolded enclosure 204. The heat slug 202 has a shape similar to an inverted “T”, and the sides 206, 208 of the heat slug 202 contact the sides 210, 212, respectively, of the substrate body 106. The heat slug 202 may be inserted mechanically (e.g., press fit) into the cavity 114 and held in place by the pressure applied by the sides 210, 212 of the substrate body 106 to the sides 206, 208 of the heat slug 202. In such embodiments, the amount of engineered filler material 116 that is used to fill the cavity 114 can be reduced. Additionally or alternatively, the bottom heat plate 122 may be omitted and replaced by the bottom surface 124 of the heat slug 202. An electrical connection to the heat slug 202 can be obtained via the bottom surface 124. In other embodiments, the heat slug 202 can have a different shape, a different size, and/or a different position or orientation in the cavity 114.

The overmolded enclosure 204 is disposed over the top surface of the substrate 102 and over and around the electronic device 108. In a non-limiting nonexclusive embodiment, the overmolded enclosure 204 is an overmolded plastic (OMP) package structure with a molded body. The overmolded enclosure 204 enables easy handling and assembly of the integrated circuit package 200 onto a printed circuit board and/or protects the electronic device 108 from damage.

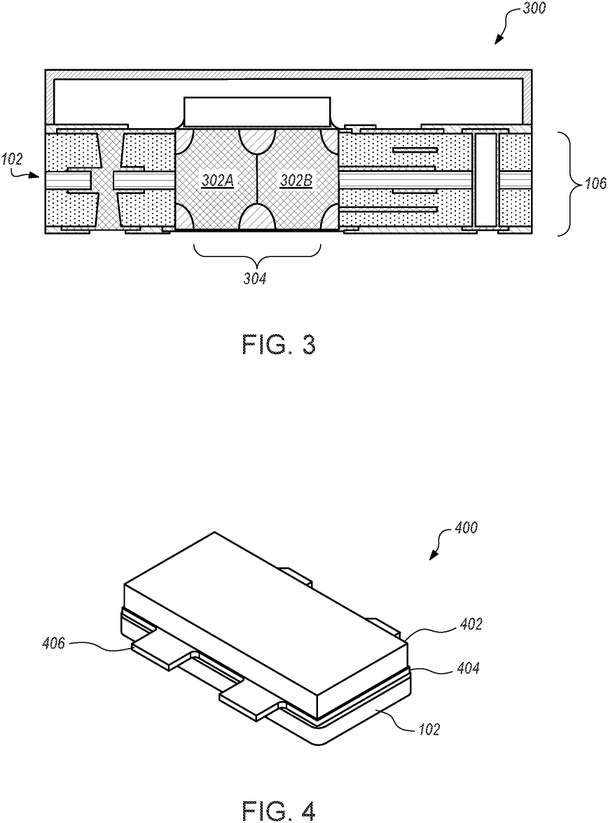

FIG. 3 illustrates a third cross-sectional side view of an example integrated circuit package 300 showing a substrate 102 with multiple heat slugs 302A, 302B embedded therein in accordance with embodiments of the disclosure. The integrated circuit package 300 is similar to the integrated circuit package shown in FIG. 1 except for the example heat slugs 302A, 302B disposed in the cavity 114. The heat slugs 302A, 302B form a heat slug array 304, where the heat slugs 302A, 302B are formed of the same conductive material or of different conductive materials. For example, the heat slug 302A may be formed of CMC and the heat slug 302B of AIN. Additionally or alternatively, the example heat slugs 302A, 302B are depicted as having the same shape and size, but other embodiments are not limited to this implementation. The shape and/or the size of the heat slug 302A can differ from the shape and/or the size of the heat slug 302B.

FIG. 4 illustrates an example integrated circuit package 400 in accordance with embodiments of the disclosure. The integrated circuit package 400 includes the substrate 102, a cover 402, and a ring frame 404 disposed between the substrate 102 and the cover 402. The substrate 102 is any suitable type of substrate. In one embodiment, the substrate is formed with a dielectric material or composite, such as a glass-reinforced epoxy resin laminate material (e.g., an Fr-4 material). The cover 400 can be implemented as a lid (e.g., the lid 110 in FIG. 1) or as an overmolded enclosure (e.g., the overmolded enclosure 204 in FIG. 2).

The ring frame 404 may be made of any suitable material or materials. In an example embodiment, the ring frame 404 is made of dielectric or organic material(s). In FIG. 4, the ring frame 404 includes four leads 406 that are used to electrically connect one or more electronic devices in the integrated circuit package 400 (e.g., the electronic device 108 in FIGS. 1-3) to another electronic component. In one embodiment, the leads 406 are formed with the material in the ring frame 404 and then the exterior surfaces are metalized (e.g., plated with copper). The ring frame can include one or more leads in other embodiments.

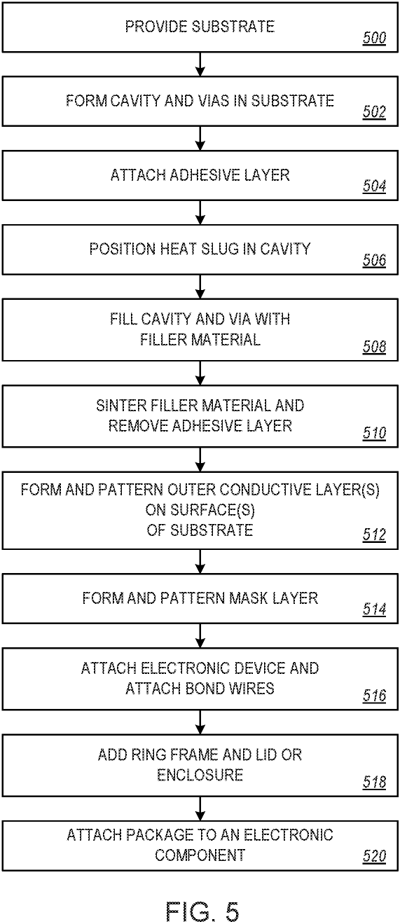

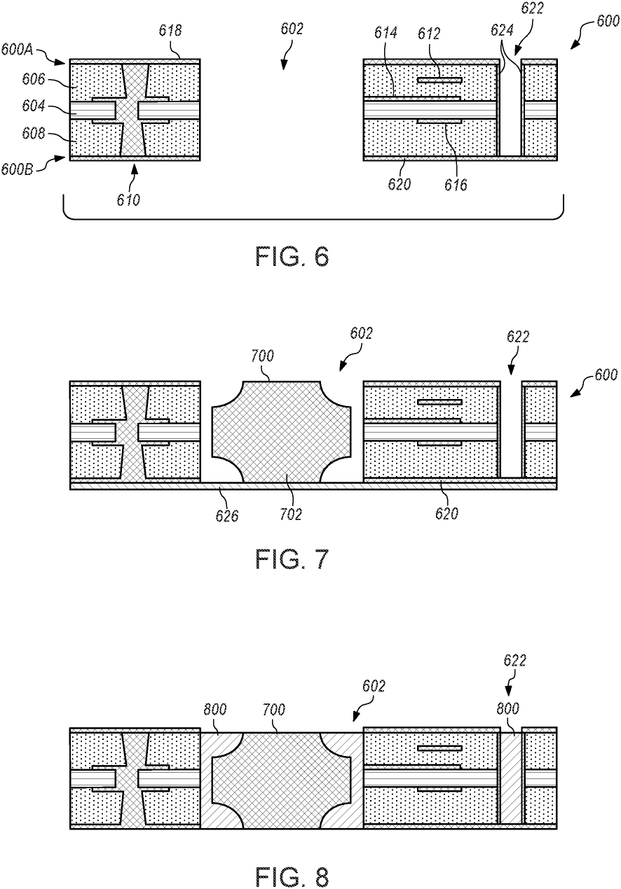

FIG. 5 illustrates an example flowchart of providing an integrated circuit package in accordance with embodiments of the disclosure. The flowchart is described in conjunction with FIGS. 6-11. Although FIG. 5 is described in conjunction with one heat slug, one electronic device, two via structures, three routing lines, and one wire bond, other embodiments are not limited to this implementation. The example method can be used to provide an integrated circuit package that includes any number of heat slugs, electronic devices, via structures, routing lines, and wire bonds.

Initially, as shown in block 500, the substrate is provided. As discussed earlier, the substrate is a laminate substrate in one embodiment. A cavity for a heat slug is formed in or through the substrate at block 502. Vias are also formed in the substrate at block 502. The cavity and one or more vias may be formed in the substrate during the same fabrication step or in different fabrication steps. In a non-limiting nonexclusive example, the cavity and the vias are formed in the substrate by mechanically drilling the substrate.

FIG. 6 illustrates an example substrate 600 with a cavity 602 formed therein in accordance with embodiments of the disclosure. The example substrate 600 is shown at a point of the fabrication process where the substrate 600 includes the laminate core layer 604, an upper dielectric layer 606 disposed over a side of the laminate core layer 604, a lower dielectric layer 608 positioned over the opposing side of the laminate core layer 604, a via structure 610, and routing lines 612, 614, 616. A top conductive layer 618 is disposed over the top surface 600A of the substrate 600. A bottom conductive layer 620 is disposed over the bottom surface 600B of the substrate 600.

The cavity 602 is formed through the top conductive layer 618, the upper dielectric layer 606, the laminate core layer 604, the lower dielectric layer 608, and the bottom conductive layer 620. In addition to the cavity 602, a via 622 is formed through the top conductive layer 618, the upper dielectric layer 606, the laminate core layer 604, and the lower dielectric layer 608. A conductive material 624, such as the conductive material in the top conductive layer 618, is disposed over the sides of the via 622. For example, sides of the via 622 may be plated with the conductive material 624.

Returning to FIG. 5, after the cavity and the via(s) are formed in the substrate, an adhesive layer is attached to the bottom conductive layer (block 504). In a non-limiting nonexclusive example, the adhesive layer is a sacrificial layer, such as a tape. The heat slug is positioned in the cavity at block 506. In non-limiting nonexclusive examples, the heat slug includes at least one of Cu, MoCu, CMC, CPC, SCMC, or AIN. The heat slug can have any size, shape, position, and/or orientation in the cavity.

FIG. 7 illustrates the substrate 600 with a heat slug 700 positioned in the cavity 602 in accordance with embodiments of the disclosure. The adhesive layer 626 is attached to the bottom conductive layer 620. A part of the adhesive layer 626 is exposed in the cavity 602. The bottom surface 702 of the heat slug 700 contacts the adhesive in the exposed adhesive layer 626. The adhesive maintains the positioning of the heat slug 700 within the cavity 602.

Next, as shown in block 508 of FIG. 5, the cavity and the via are filled with the engineered filler material. As discussed previously, in one embodiment the engineered filler material is a nano-copper (E-Cu) particle material. The engineered filler material can be dispensed into the cavity and the via during the same fabrication step, or the engineered filler material can be dispensed into the cavity and the via during separate fabrication steps. In one embodiment, the engineered filler material in the cavity and in the via has the same composition. In another embodiment, the composition of the engineered filler material in the cavity may differ from the composition of the engineered filler material in the via. FIG. 8 illustrates the engineered filler material 800 disposed in the via 622 and in the cavity 602 around the heat slug 700 in accordance with embodiments of the disclosure.

The engineered filler material is sintered at block 510 to cause the engineered filler material to form into a solid. The adhesive layer can be removed before or after the engineered filler material is sintered. A grinding operation may be performed to planarize the top and/or bottom surfaces of the engineered filler material.

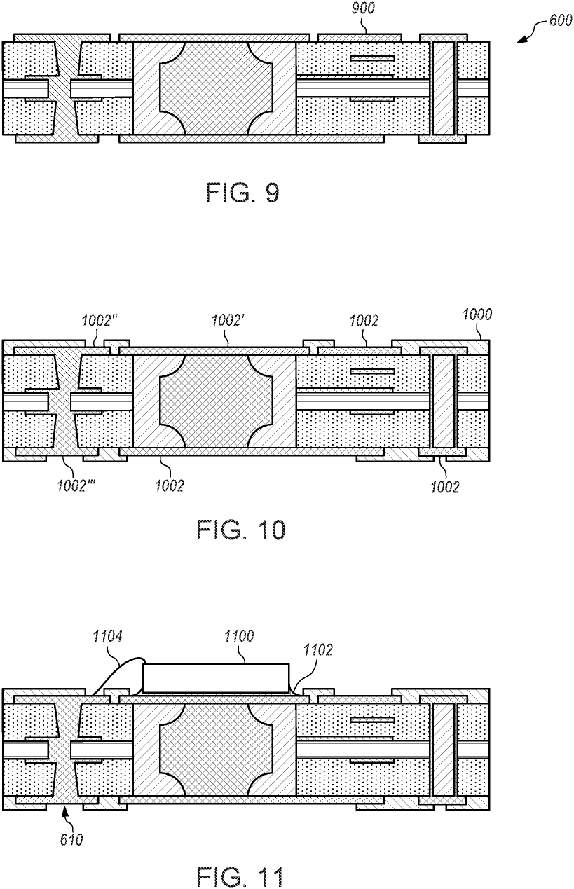

Next, as shown in block 512, an outer conductive layer is formed over the top surface and/or the bottom surface of the substrate and patterned. The outer conductive layer(s) can be formed by an additive process or by a subtractive process. In a subtractive process, conductive material is formed over the surface and some or all of the conductive material is selectively removed (e.g., etched). In an additive process, conductive material is plated over select areas of the surface. FIG. 9 illustrates the substrate with patterned outer conductive layers 900 disposed over the top and the bottom surfaces of the substrate 600 in accordance with embodiments of the disclosure.

Referring again to FIG. 5, a mask layer is formed and patterned over the patterned outer conductive layers. The mask layers limit the exposure of the outer conductive layers to select sections of the outer conductive layers. FIG. 10 illustrates patterned mask layers 1000 disposed over select areas of the patterned outer conductive layers in accordance with embodiments of the disclosure. Sections 1002 of the outer conductive layers are exposed and can be used to electrically connect the exposed outer conductive layers to the electronic device and/or to other electronic components. In FIG. 10, the section 1002′ is similar to the top heat plate 118 shown in FIG. 1, the section 1002″ is similar to the top via pad 130A shown in FIG. 1, and the section 1002‴ is similar to the bottom via pad 130A shown in FIG. 1.

An electronic device is attached to the substrate at block 516. The electronic device can be attached to the substrate with a die attach material, such as a low-temperature die attach material. In another embodiment, the electronic device may be attached to the substrate with the engineered filler material. After the electronic device is attached to the substrate, one or more wire bonds are attached between the electronic device and one or more outer conductive layers to electrically connect the electronic device to the outer conductive layer(s).

FIG. 11 illustrates an electronic device 1100 attached to the section 1002′ (FIG. 10) of the outer conductive layer with a die attach material 1102 in accordance with embodiments of the disclosure. As described earlier, the engineered filler material can be used to attach the electronic device 1100 to the section 1002′ of the outer conductive layer.

A wire bond 1104 is attached to the electronic device 1100 and to the section 1002″ of the outer conductive layer. The wire bond 1104 electrically connects the electronic device 1100 to the section 1002″. In the illustrated embodiment, the via structure 610 is filled with a conductive material, such as copper. Thus, the electronic device 1100 is electrically connected to the section 1002‴ of the outer conductive layer (FIG. 10) through the wire bond 1104, the section 1002″ of the outer conductive layer, and the via structure 610.

Referring now to block 518 in FIG. 5, a ring frame is positioned over the substrate and a lid or overmolded enclosure is disposed over the substrate. The ring frame includes one or more leads or pins that are electrically connected to the electronic device and extend out from the integrated circuit package. An example ring frame is shown in FIG. 4.

The lid or the overmolded enclosure is disposed over the substrate and the electronic device. FIG. 1 depicts a lid 110 disposed over the substrate and the electronic device. FIG. 2 shows an overmolded enclosure 204 disposed over the substrate and the electronic device. Together the substrate, the electronic device, the ring frame, and the lid or the overmolded enclosure form an integrated circuit package.

The integrated circuit package can be attached to one or more electronic components at block 520. An example of an electronic component is a printed circuit board. The integrated circuit package may be attached to the printed circuit board using a ball grid array, by soldering the leads of the ring frame to the printed circuit board, or by any other suitable technique. Additionally or alternatively, the integrated circuit package may be attached to another type of electronic component.

Other embodiments are not limited to the operations and the order of the operations shown in FIG. 5. One or more blocks may be added, rearranged, or omitted and/or the operations represented by a block modified. For example, when a heat slug is press fitted into a cavity, such as the heat slug 202 shown in FIG. 2, block 504 can be omitted. Accordingly, block 510 does not need to include the operation of removing the adhesive layer. Additionally or alternatively, a via may not be filled with the engineered filler material in block 508. Instead, the via can be filled with a non-conductive material (e.g., an epoxy resin). In some embodiments, the cavity formed at block 502 may be formed in only a portion of the substrate and not extend through the substrate as shown in FIG. 6.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A substrate, comprising:
a heat slug disposed in a cavity in the substrate, the heat slug formed of a conductive material; and
an engineered filler material disposed in the cavity over the heat slug, the engineered filler material comprising a thermally and electrically conductive particle material.

2. The substrate of claim 1, wherein further comprising a routing line disposed in the substrate and electrically connected to the heat slug via the engineered filler material.

3. The substrate of claim 1, further comprising a via structure, the via structure comprising:
a via formed in the substrate;
a conductive material disposed over a first side and a second side of the via; and
the engineered filler material disposed in the via between the first and the second sides of the via.

4. The substrate of claim 1, further comprising a via structure, the via structure comprising:
a via formed in the substrate; and
a conductive material disposed in the via.

5. The substrate of claim 1, wherein a coefficient of thermal expansion (CTE) of the engineered filler material is between the CTE of the heat slug and the CTE of the substrate.

6. The substrate of claim 1, further comprising:
an outer conductive layer disposed over a surface of the substrate; and
a mask layer disposed over a portion of the outer conductive layer.

7. The substrate of claim 1, wherein the cavity extends through the substrate from a top surface of the substrate to a bottom surface of the substrate.

8. The substrate of claim 1, wherein the heat slug is included in a heat slug array, the heat slug array comprised of multiple heat slugs.

9. An integrated circuit (IC) package, comprising:
a cavity formed in a substrate;
a heat slug disposed in the cavity, the heat slug formed of a thermally and electrically conductive material;
an engineered filler material disposed in the cavity over the heat slug, the engineered filler material comprising a thermally and electrically conductive particle material; and
an electronic device attached, via a die attach material, to the substrate over the heat slug, the heat slug and the engineered filler material providing a heat transfer dissipation path for the electronic device.

10. The IC package of claim 9, wherein the engineered filler material is a nano-copper particle material.

11. The IC package of claim 9, wherein the die attach material is the engineered filler material.

12. The IC package of claim 9, further comprising a via structure formed in the substrate, the via structure comprising:
a via formed in the substrate;
a conductive material disposed over a first side and a second side of the via; and
the engineered filler material disposed in the via between the first and the second sides of the via.

13. The IC package of claim 9, further comprising a wire bond attached to the electronic device and attached to an outer conductive layer that is disposed over a surface of the substrate.

14. The IC package of claim 9, wherein:
the heat slug is electrically grounded; or
the heat slug is operable to propagate a signal.

15. The IC package of claim 9, further comprising a lid attached to the substrate, the substrate and the lid defining an air space therebetween with the electronic device positioned within the air space.

16. The IC package of claim 9, further comprising an overmolded enclosure disposed over the substrate and the electronic device.

17. A method, comprising:
disposing a heat slug in a cavity of a substrate, the heat slug formed of a conductive material; and
forming an engineered filler material in the cavity over the heat slug, the engineered filler material comprising a conductive particle material; and
attaching an electronic device over the substrate, the heat slug and the engineered filler material included in a heat transfer dissipation path for the electronic device.

18. The method of claim 17, wherein:
attaching the electronic device over the substrate comprises attaching the electronic device over the substrate with a die attach material; and
the die attach material is the engineered filler material.

19. The method of claim 17, further comprising:
forming a via in the substrate; and
forming the engineered conductive material in the via.

20. The method of claim 17, attaching a lid to the substrate, the substrate and the lid defining an air space therebetween with the electronic device positioned within the air space.
